(19) United States
(12) Patent Application Publication
(10) Pub. No.: US 2013/0068271 A1
(43) Pub. Date: Mar. 21, 2013

(54) Prototype Thermoelectric Generator Based on Ionized Gas in a Container Under Electric Potential Difference

(71) Applicant: Mohammad Jamil Ahmad Bqoor, Salt (JO)

(72) Inventor: Mohammad Jamil Ahmad Bqoor, Salt (JO)

(21) Appl. No.: 13/110,944

(22) Filed: Sep. 20, 2011

(51) Int. Cl. H01L 35/30

(52) U.S. Cl. 136/205

(57) ABSTRACT

In this prototype Thermoelectric Generator (TEG), a new configuration of ionized gas in a container under electric potential difference has been theoretically studied. This device is proposed to generate electric power from ambient air based on the Kinetic Theory of Gases. This prototype TGE has been designed based on the idea of making a number of ionic molecules move toward a selected direction. This prototype TEG has a similar functionality to that of photovoltaic device that is confined by the statistical limits of energy distribution over photons that have the ability to make a photoelectric effect releasing free electrons with energies greater than the voltage threshold, but in this prototype TEG, the advantage is taken from extracting power directly from the moving molecules forming gas. This design is convenient to be installed indoors to produce cold air and generate electric power.

### FIELD OF THE INVENTION

The present invention relates to the field of electrostatic, electrodynamics and the kinetic theory of gases. Furthermore; the present invention relates by the means of working mechanism to the photovoltaic devices that extract power from light.

### Usage and Manufacturing

The present invention is used to extract electrical or mechanical power from thermal energy of ambient air, the manufacturing of this present invention is fairly simple, it comprised of electrically insulating closed circular pipe containing fixed electrically insulated permanent positive and negative electrodes, the circular closed pipe is filled with mixture of ionized and neutral gas. In the manufacturing process of this invention, it is recommended to start with:
1—The first stage is to fill the circular closed pipe with the stable gas (for instance He gas) with the appropriate pressure in order to optimize the efficiency of this TEG.
2—The second stage is dual process, simultaneously charging the negative electrodes and filling the circular pipe with the positive ionized gas in case of the usage of positive ionized gas, or charging the positive electrodes and filling the circular pipe with the negative ionized gas in case of the usage of negative ionized gas, where these electrodes are placed in the circular pipe (D+d) arc distance from each others, and the positive ionized gas for instance can be proton particles (ionized Hydrogen). This simultaneously process is important in order to reduce the energy required to assembly the ionized gas molecules.
3—The third stage is to put the rest of electrodes in their positions in the circular pipe (d) arc distance adjacent to the electrodes mentioned in the second stage, where the magnitude of the distance (D) is greater than the distance (d).
4—The fourth stage is to install the power extraction system, which is simply an electric inductance circuit parallel to the circular pipe with a core metal as a central axis for both inductance circuit and the circular pipe. An alternative power extraction system is electric generator connected to a fan (with appropriate size and capacity) and located inside the circular pipe.

### BRIEF DESCRIPTION OF THE DRAWINGS

FIG. 1.(a). Perspective (x,y) plane view of the electrically insulating closed circular pipe and a number of positive and negative electrodes distribute around the circular pipe in the present invention. (b) perspective (x,y) plane view for part of the circular pipe containing four electrodes and schematically showing positive molecules surrounding the negative electrode. (c) cross sectional (y,z) plane view showing the electrical insulation surrounding the electrodes.

FIG. 2.(a). Electric potential (V_{eld}) produced by a sequence of six electrodes and electric potential (Vᵢₒₙ) produced by the free ionic gas molecules in this present invention. (b). the resulting electric potential of the system of six electrodes and the ionic gas molecules showing the three ionic gas molecules regions of equipotential (V_{eq}) in this present invention.

FIG. 3. Spatial distribution of six electrodes in the (x,y) plane showing the distances separating positive and negative electrodes in this present invention.

FIG. 4. Perspective (x,z) plane view of three clouds of positive molecules formed by a sequence of six electrodes, showing the spatial distances (D, d) between these six electrodes.

FIG. 5. The electric potential of the present invention after injection of one positive molecule.

FIG. 6. The electric potential of the present invention after injection of seven positive molecule.

FIG. 7. Perspective (x,z) plane view showing electric potential of the present invention corresponding to its perspective location in the system.

FIG. 8. Maxwell distribution of energy for ionic gas molecules in the present invention.

FIG. 9. Maxwell distribution of x-component energies of ionic gas molecules, showing the fraction of molecules having of x-component energies greater than the threshold of the present invention.

FIG. 10. Internal current of positive molecules paths in the x-axes, showing the recoiling of this current from electric potential barriers of the present invention.

FIG. 11. The relation between the produced current (Iⁿ) of neutral molecules and the mean free path (λ) of mixed gas contained in the circular pipe in the present invention.

While the above-identified disclosure and drawing figures set one forth preferred embodiment, numerous other embodiments of the present invention are also contemplated. In all cases, this disclosure presents the illustrated embodiments of the present invention by way of representation and not limitation. Numerous other minor modifications and embodiments can be devised by those skilled in the art which fall within the scope and spirit of the principles of this invention.

### DETAILED DESCRIPTION

### Introduction

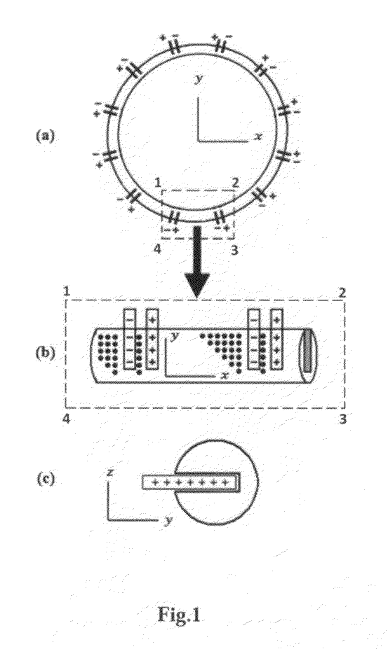

The prototype Thermoelectric Generator (TGE) general layout is shown in FIG. 1, this TGE is designed to convert kinetic energy of gas molecules (heat energy) into electrical energy using neutral stable gas (for instance, He gas) mixed with charged ionic gas contained in an electrically insulating closed circular pipe, and a sequence of fixed positive and negative electrodes arranged as shown in FIG. 1, these positive and negative electrodes are homogenously charged with positive and negative charge carriers fixed in positions, and electrically insulated from the charged ionic gas molecules contained in the circular pipe, thus the non-conducting property of the circular pipe is to keep ionic gas away from interaction (charge transfer) with the electrodes and the surroundings.

### Design

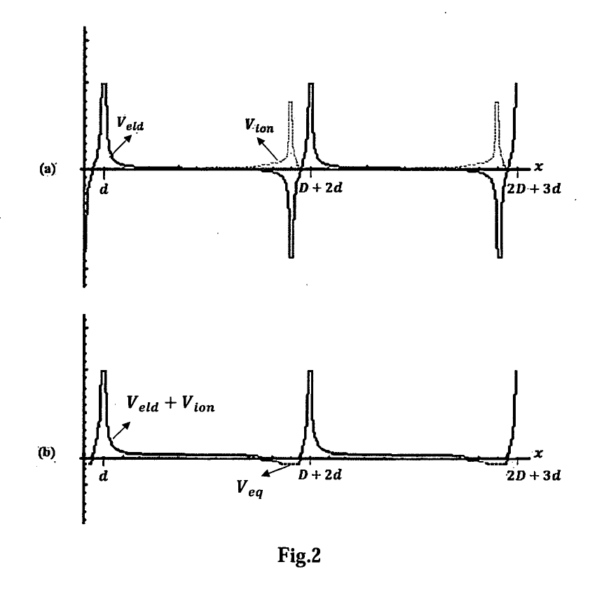

Assuming positively charged ionic molecules, from FIG. 1, since the ionic gas molecules are free to move inside the circular pipe, these molecules will be distributed so that every ionic molecule will be laid at some positions that satisfy (at electrostatic state, i.e. TEG system at absolute zero temperature):
Equal electric potential (V_{eq}) for every free ionic gas molecules inside the TEG system as shown in FIG. 2.(b).
Occupying positions with minimal total electric potential energy.

While at electrodynamics state (i.e. TEG system temperature greater than absolute zero), the free ionic gas molecules will start its vibrational or transportational motion depending on their individual energies. The voltage curve produced by the sequence of electrodes (V_{eld}) and the voltage produced by the distribution of free ionic gas molecules (Vᵢₒₙ) are shown in FIG. 2.(a). The voltage (V_{eld}) can be evaluated according to Eqn. (1). The net voltage of the system will be simply the addition of these two lines as shown in FIG. 2(b), where the free ionic gas molecule will be located at the equal potential line (V_{eq}) as shown in FIG. 2(b).

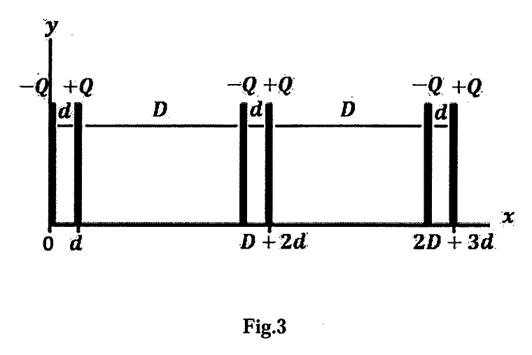

To estimate the electric potential for a sequence of electrodes; V_{eld} (x), taking an arbitrary sequence of six electrodes (negative, positive, negative, positive, negative, positive) as shown in FIG. 3, the voltage of this sequence will be:

$${V}_{eld} = \frac{1}{4 πɛ} ( \frac{- Q}{\vert x \vert} + \frac{+ Q}{\vert x - d \vert} + \frac{- Q}{\vert x - d - D \vert} + \frac{+ Q}{\vert x - 2 d - D \vert} + \frac{- Q}{\vert x - 2 d - 2 D \vert} + \frac{+ Q}{\vert x - 3 d - 2 D \vert} ) \qquad ( 1 )$$

The contributions of the other electrodes rather than the six where considered in Eqn.(1) can be neglected; because of the symmetry of the system, that these six electrodes assumed to be in a line, while the other radial electrodes will vanish their effects, because of that a positive electrode placed at a distance (r₁) will vanish the effect of the adjacent negative electrode placed at (r₂) where:

r₁≈r₂

Noting that the electric potential in FIG. 2 goes to infinite (minus infinite) as going closer to positive (negative) electrodes, but this is not the case as in this TEG design shown in FIG. 1(c), where open space around the electrodes as shown in FIG. 1(c) produces finite electric potential peaks for the different paths beside the electrodes, then the real TEG electric potential will be the same as in FIG. 2; but with finite peaks at:

x=d;D+d;D+2d,etc.

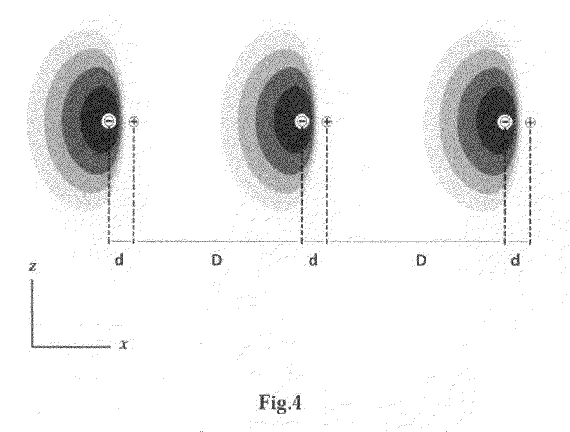

Physically, the maximum density of the positive ionic molecules will be laid in the vicinity of the negative electrodes, forming a clouds of positive ionic molecules encircling negative electrodes, the density of these clouds will decrease as moving away from negative electrodes and getting closer to positive electrodes as shown in FIG. 4. To figure out the characteristics of this positive cloud, it's convenient to consider the x-z plane, and assuming the electrodes are tall enough to be considered infinite lines parallel to the y-axis; then equally spacing between the positive molecules in the y-axis can be justified. Since the electrodes seems to be point charges in the x-z plane as seen from y-axis (FIG. 4), the distribution can be simulated using computer applets for electric potential field produced by number of point charges^{[1]}.

FIG. 4 shows the positive clouds at x-z plane due to a sequence of point charges, noting that every positive (negative) electrode charged with fixed charge of +Q (−Q), and the positive molecules have individual charges (q), where (|Q|>>q). The working mechanism of this TEG design is based on the followings:
1. The maximum charge density is located in the vicinity of the negative electrode, and;
2. The existence of the geometry (D≠d) as shown in FIG. 4, and;
3. The existence of positive potential barrier (net potential difference) at the positive electrodes.

The characteristics of the positive cloud can be understood by interjecting of the positive molecules one by one, and every added molecule will be placed at a position satisfying the basic two conditions for the stability of electrostatic systems, namely:
1. Any positive molecule will be laid in a position satisfying equipotential for the whole arrangement of positive molecules.
2. The electric potential energy of the n-th free ionic gas molecule;

E_{add}⁽ⁿ⁾
injected to the system should be minimal, and this can be achieved by start filling positions at the most negative electric potential points, i.e. the adjacent points encircling the negative electrodes as shown in FIG. 4.

To estimate the distribution of positive molecules numerically, it's convenient to start with the following assumptions:

1. d=1 distance unit

2. D=10 d=10 distance units;

3. q=1 charge unit;

4. Q=10 q=10 charge units;

Then the electric potential unit is:

$$\frac{kq}{d} ; k = \frac{1}{4 πε} \qquad ( 2 )$$

And one more important assumption that the insulation distance surrounding the negative electrodes is:

Δ=0.1 distance units

From FIG. 4, assuming that the x-axis passes through the electrodes, then the distribution of the positive molecules over x-axis will give a good indicator for the distribution of positive molecules inside the cloud. The position of the first positive molecule in the x-axis can be evaluated using the minimizing energy condition:

$$\frac{d}{dx} {E}_{add}^{( n )} ( x ) = \frac{d}{dx} qV ( x ) = 0 \qquad ( 3 )$$

Where x is the position that the injected molecules will be located in, and V (x) is the electric potential at the position (x). From FIG. 2.(a) and Eqn. (3), it's obvious that the position of the first molecule will be located somewhere at the negative electric potential peaks; i.e.:

D+d,2D+2d, . . .

And because of the insulation distance, the position will be either:

x=D+d−Δ or x=D+d+Δ;
i.e. (x=10.9 distance units) or (x=11.1 distance units)

From the arrangement shown in FIG. 3, and Eqn.(3), the corresponding energy for each of these locations can be derived as (for 4-electrodes):

$${E}_{add}^{( 1 )} ( x ) = \frac{kQq}{d} ( \frac{- 1}{x} + \frac{1}{x - 1} + \frac{- 1}{\vert 11 - x \vert} + \frac{1}{12 - x} ) ; x ∈ [ 1 , 12 ] \qquad ( 4 )$$

Since d=1 distance unit, hence x is in the units of d, Then:

E_{add}⁽¹⁾(10.9)=−9.082 (kQq/d)

E_{add}⁽¹⁾(11.1)=−8.880 (kQq/d)

So that the first positive molecule will be placed at (x=10.9) according to the energy minimization condition. To find the second molecule position, the electric potential effect due to the first positive molecule with charge (q=0.1 Q) should be introduced into Eqn. (4), hence:

$${E}_{add}^{( 2 )} ( x ) = \frac{kQq}{d} ( \frac{- 1}{x} + \frac{1}{x - 1} + \frac{- 1}{\vert 11 - x \vert} + \frac{1}{12 - x} + \frac{0.1}{\vert 10.9 - x \vert} ) \qquad ( 5 )$$

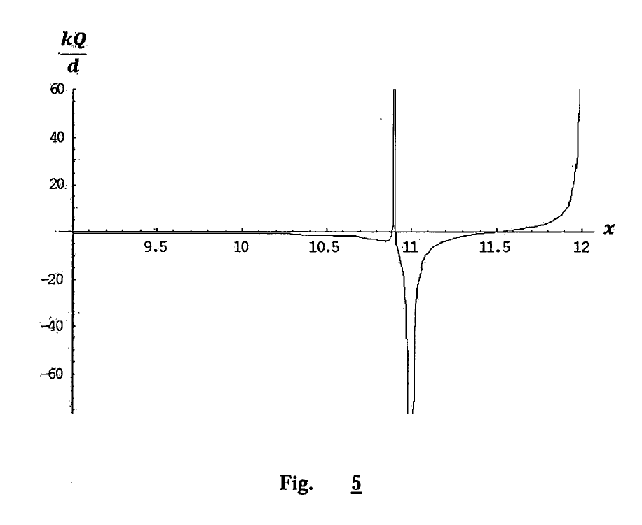

To find the locations with local minimal electric potential energies rather than (x=11.1), FIG. 5 shows the electric potential produced by Eqn.(5), showing some local minimal energy lied in between (x=10.8 and x=10.9).

To find this local minimum, the first derivative with respect to x of Eqn. (5) is:

$$\frac{d}{dx} {E}_{add}^{( 2 )} ( x ) = \{ \begin{matrix}\frac{1}{{x}^{2}} + \frac{- 1}{{( x - 1 )}^{2}} + \frac{- 1}{{( 11 - x )}^{2}} + \frac{1}{{( 12 - x )}^{2}} + \frac{0.1}{{( 10.9 - x )}^{2}} ; 1 < x \leq 10.9 \\ \frac{1}{{x}^{2}} + \frac{- 1}{{( x - 1 )}^{2}} + \frac{1}{{( x - 11 )}^{2}} + \frac{1}{{( 12 - x )}^{2}} + \frac{- 0.1}{{( x - 10.9 )}^{2}} ; 11.1 \leq x < 12\end{matrix} \qquad ( 6 )$$

Then applying the condition in Eqn.(3) into Eqn.(6), will give a local minimal energy at (x=10.853), and this position to be competed with the position (x=11.1) for hosting the second positive molecule, then according to Eqn. (5); the followings are the corresponding electric potential energies for the competing locations:

E_{add}²(11.1)=−8.38 (kQq/d)

E_{add}²(10.853)=−3.79 (kQq/d)

Then the position (x=11.1) is selected for hosting the second positive molecule. For the third positive molecule, the effect of the second injected molecule should be introduced by adding one more term to Eqn. (5) representing the existence of the second positive molecule at (x=11.1), and then repeat the same procedures for calculating positions of local minimal energies.

Repeating this process for the first seven molecules will give the following positions:

x=10.461;10.747;10.851;10.9;11.1;11.147;11.237

These locations affirms the expected decreasing of charge density while moving far from the negative electrode placed at (x=11.0).

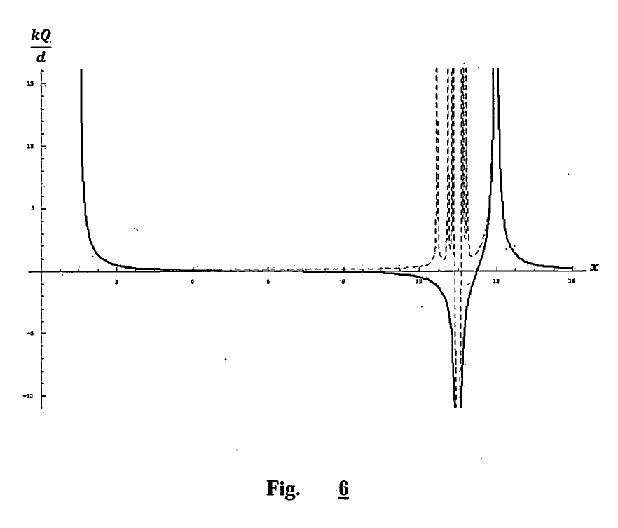

These positions are shown in FIG. 6, as seven positive electric potential peaks surrounding the negative electrode located at (x=11), where the spacing between these points increase as moving far from the negative electrode (decreasing of charge density).

FIG. 6 shows that the majority number of positive molecules in this design is laid in the vicinity of negative electrodes, as expected result for the positive cloud shown in FIG. 4.

Indeed; the preceding seven injected molecules are not fixed in position; these molecules will be shifted (comprised) toward the negative electrode after every injection of additional positive molecule to the system, excluding the two positive molecule in positions (x=10.9) and (x=11.1) that are not able to be much closer to the negative electrode because of insulation, where the bases of the remaining five positive molecules potential peaks should be laid on the same horizontal line that is equal to the equipotential (V_{eq}) shown in FIG. 2.(b), this shift will increase the density in the vicinity of negative electrodes. In general; the preceding calculation is only giving the indicators to understand the distribution of positive molecules forming the positive cloud shown in FIG. 4.

### Working Method

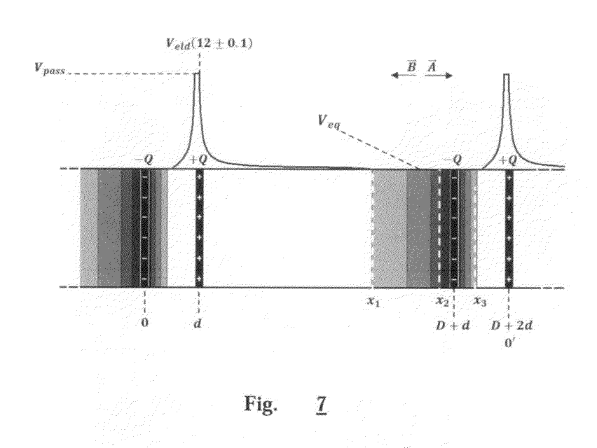

The high charge density in the vicinity of the negative electrode plays the main rule in the working mechanism of this TEG design. Based on the characteristics of the positive cloud surrounding negative electrodes, and the distribution of positive and negative electrodes shown in FIG. 3, the TEG design can be schematically introduced as shown in FIG. 7, where the number of positive molecules (Nₘ)) and its individual charges (q) should be chosen so that the threshold potential (Vₚₐₛₛ) shown in FIG. 7 kept positive at all working conditions (pressure, temperature, etc.), where (Vₚₐₛₛ) is the electric potential difference between the equipotential line (V_{eq}) and the electric potential peak adjacent to the positive electrode, namely;

V_{eld}(x=D+2d±Δ,2D+3d±Δ,etc.)=V_{eld}(12±0.1)

Then:

Vₚₐₛₛ=[V_{eld}(12±0.1)−Vᵢₒₙ]>0 (7)

From FIG. 7, by principle; any positive molecule has energy greater than (qVₚₐₛₛ) will be electrically capable to across any positive electrode threshold in both directions (\vec{A} and \vec{B}) shown in FIG. 7.

Thereafter; the rule of the neutral stable gas come to place, where the neutral gas is mixed with the ionic positive gas, these neutral molecules will not be affected by the electric potential of the system, and will be distributed in such a manner that equalizes the pressure of the container (circular pipe).

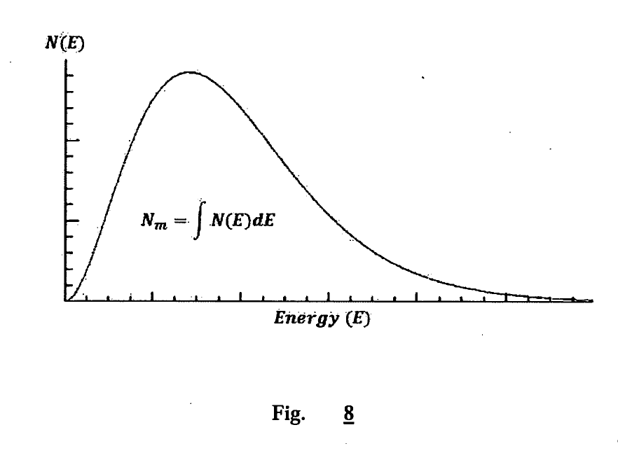

Assuming the mixed gas to be treated as a classical gas; the energy distribution of the mixed gas will obey the Maxwell distribution of energy. Since the ionic gas is mixed with the neutral gas; the molecules of ionic gas should have the same Maxwell distribution of energy as the mixed gas, but with different magnitude of kinetic energies, because some portion of thermal energy gained by the ionic gas will be stored as electric potential energy, then the energy distribution over the (Nₘ) positive molecules will be as shown in FIG. 8.

The energy acquired by every positive molecules according to FIG. 8 will allow expansion of the layers shown in FIG. 7, but keeping the cloud with the same configuration but with different size of layers, where the positive molecules having x-component kinetic energies (Eₓ) less than threshold energy (Eₓ<qVₚₐₛₛ) are not capable to, across the positive thresholds. Henceforth; the attention will be given to the positive molecules having Eₓ greater than the threshold energy, i.e.:

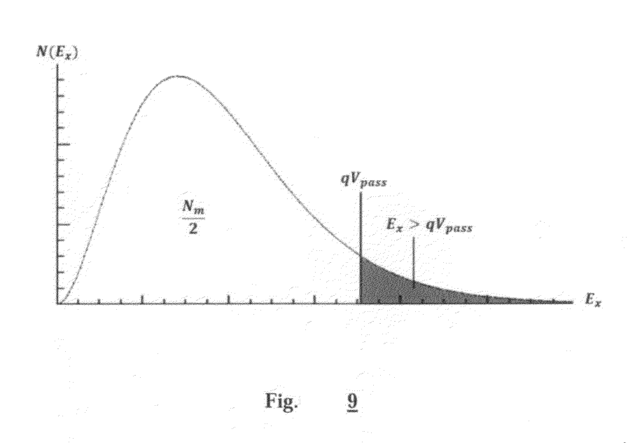

Eₓ>qVₚₐₛₛ

In which only these molecules will have the probability to across (Vₚₐₛₛ) thresholds. According to the kinetic theory of gases, the gas molecules are equally likely to be moving in any direction^{[2]}, then; the distribution of positive particles according to their (Eₓ) energies will have the same Maxwell distribution of positive molecules, but with different scale of N(E), as shown in FIG. 9.

Regarding ionic gas molecules having (Eₓ>qVₚₐₛₛ), according to the kinetic theory of gases; half of these molecules will be traveling across thresholds in the direction (\vec{A}), and the other half will be traveling in the direction (\vec{B}) shown in FIG. 7, also according to the kinetic theory of gases; every traveling molecule will experience collisions with the mixed gas molecules throughout its traveling path, and from FIG. 7, and noting that:
a) All positive molecules are at the same equipotential line (Vᵢₒₙ), that is every positive molecule have (Eₓ>qVₚₐₛₛ) will be electrically capable to across thresholds from any starting point inside the positive cloud.
b) There must be some point (x₂), in which half of positive molecules are placed in the region (x₁<x<x₂), and the other half are placed in the region (x₂<x<x₃) as shown in FIG. 7.
c) The symbol 0′ in FIG. 7 is chosen to denote the starting of a similar adjacent system.

Then; half of the number of traveling positive molecules can be considered to start its track from (x=x₂) toward the direction (\vec{A}), and the other half to start its track from (x=x₂) toward the direction (\vec{B}), where the position of the starting point (x₂) is much closer to (x₃) than to (x₁), because of the high density of positive molecules in the vicinity of negative electrodes.

The mobile charges in this system are categorized as a heavy particles compared to other elementary particles, where heavy charged particles have a straight tracks inside materials^{[3]}, especially in light mediums like gases, then; it's convenient to introduce the linear stopping power (S) to represent the specific energy loss (−dE/dx) for the positive molecules traveling in the medium, where ^{[3]}:

$$\begin{matrix}S = \frac{- dE}{dx} & ( 8 ) \\ Then \text{:} & \\ Δ E = - S Δ x & ( 9 )\end{matrix}$$

Where (S) is the stopping power of positive molecules in the mixed gas, the value of S depends on the mass and charge of mobile molecules, and the material, temperature and pressure of the medium the particle passing through. The probability (P) of positive molecules to pass through thresholds in the directions (\vec{A}) and (\vec{B}) will linearly depend on the inverse of energy loss of these traveling molecules, From Eqn.9; the energy loss can be calculated as:

$$\begin{matrix}{P}_{\vec{A}} {∝}^{- 1} Δ {E}_{\vec{A}} = - S Δ {x}_{\vec{A}} = - S ( {0}^{′} - {x}_{2} ) \\ {P}_{\vec{B}} {∝}^{- 1} Δ {E}_{\vec{B}} = - S Δ {x}_{\vec{B}} = - S ( {x}_{2} - 0 ) \\ ( {0}^{′} - {x}_{2} ) < ( {x}_{2} - 0 ) & ( 10 ) \\ Then \text{:} & \\ \frac{{P}_{\vec{A}}}{{P}_{\vec{B}}} = \frac{{x}_{2} - 0}{{0}^{′} - {x}_{2}} > 1 & ( 11 )\end{matrix}$$

From Eqn.11, a net positive molecules current (IₜₒₜₐₗÂ) will be passing through the thresholds in the direction (\vec{A}), and the net current can be evaluated from Eqn. (11):

$$\frac{{I}_{\vec{A}}}{{I}_{\vec{B}}} ∝ \frac{{P}_{\vec{A}}}{{P}_{\vec{B}}} > 1 \\ {I}_{total} = ( {I}_{\vec{A}} - {I}_{\vec{B}} ) > 1 \qquad ( 12 )$$

Where (I_{\vec{A}}) and (I_{\vec{B}}) are the positive molecular current in the directions (\vec{A}) and (\vec{B}) respectively. To prove the continuity of the current (IₜₒₜₐₗÂ), It's important to note that if any positive molecule pass through a threshold in the direction (\vec{A}) and lose part of its energy (through S) and becomes with (Eₓ<qVₚₐₛₛ) in the region (0<x<x₁), it's most probable for this molecule to continue moving in the same direction (\vec{A}) until reach the cloud due to the drifting electric potential difference in the region (0<x<x₁), and one more thing will increase the net produced current is that if any positive molecule having (Eₓ>qVₚₐₛₛ) moving in the direction (\vec{B}) and lose part of its energy and becomes with (Eₓ<qVₚₐₛₛ) 1 in the region (0<x<x₁), it's most probable for this molecule to recoil back toward the direction (\vec{A}) due to the drifting electric potential difference in the region (0<x<x₁).

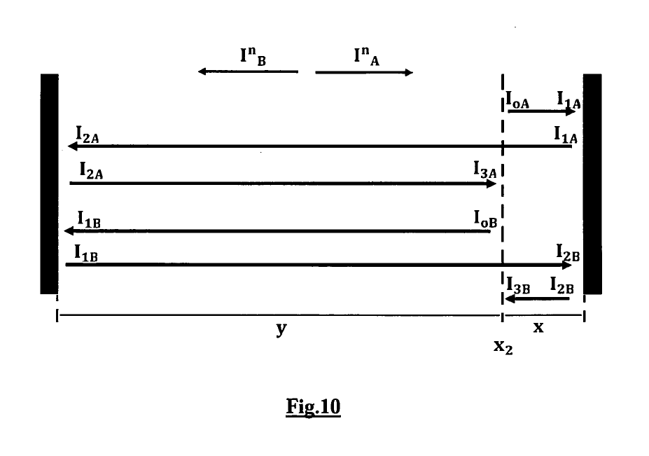

And another important notes to be considered in this system:
(1) The positive molecules in average have energy in the range (˜0.1 eV)^{[4]}, in which it will not be able to ionize atoms in the medium passing through it, therefore; there will be no energy lose through ionization or any other subatomic interactions, and the only two types of interaction that governs the motion of positive molecules in this system to be considered are:
   a) The elastic collision with mixed gas molecules and container material, this interaction will occur at every point in the system, this interaction will increase the stopping power (S), because of that the majority number of mixed gas molecules have energy less than the energy of traveling positive molecules as shown in FIG. 9.
   b) The Coulomb field interaction that occur only in the regions outside the equipotential volume (the positive cloud, x₁<x<x₃); the regions outside the cloud are located under the potential thresholds shown in FIG. 7.
(2) A reverse current of neutral molecules will be produced toward the direction \vec{B}, this current is due to the positive molecules having x-component energies less than the threshold energy, i.e. (Eₓ<qVₚₐₛₛ), where these positive molecules moving toward the direction \vec{A} will be recoiled from the closest threshold after passing shorter distance compared to thus moving toward the direction \vec{B} as shown in FIG. 10, hence the energy transferred to neutral molecules through collisions will derive the majority of these neutral molecules toward the direction \vec{B}, noting that this current will work as a resistance and limits the value of terminal current (IₜₒₜₐₗÂ), so that the threshold energy (qVₚₐₛₛ) should be chosen carefully to reduce the number of recoiled primary positive molecules with energy (Eₓ<qVₚₐₛₛ).
(3) Energy extraction can be performed by inducing external electrical current from the internal molecular current (IₜₒₜₐₗÂ).

Another proposed mechanism to extract power from this TEG system is more simple, this mechanism is based on increasing the threshold energy (qVₚₐₛₛ), that is significantly no positive molecule can pass through these thresholds, then the reverse current of neutral molecules explained in point (2) above will be increased. Hence; power can be extracted from this current of neutral molecules by using a number of fans connected to electric generators with appropriate size and power generating capacity to be putted inside the circular pipe, or allow the circular pipe shown in FIG. 1.(a) to rotate around the central axis that is parallel to z-axis, and extract power from the rotating central axis. To estimate the value of this current of neutral molecules, it is convenient to start with the assumption of two currents of positive molecules (I_{oA}) and (I_{oB}) that equal in magnitude and opposite in direction released from the point (x₂) as shown in FIG. 10. Then from FIG. 10, and from the transport equations:

$${I}_{1 A} = {I}_{oA} {e}^{\frac{- x}{λ}} = {I}_{o} {e}^{\frac{- x}{λ}}$$

$${I}_{1 B} = {I}_{oB} {e}^{\frac{- y}{λ}} = {I}_{o} {e}^{\frac{- y}{λ}}$$

Where λ is the mean free path of the mixed gas contained in the circular pipe, based on the low of conservation of linear momentum, and assuming equal mass for both positive and neutral molecules; the currents of neutral molecules (Iⁿ⁰_{A}) and (Iⁿ⁰_{B}) produced by attenuating (through elastic collisions) the two currents of positive molecules (I_{oA}) and (I_{oB}) can be derived from Eqn.(13) and FIG. 10 to be:

$${I}_{A}^{n 0} = {I}_{oA} - {I}_{1 A} = {I}_{o} ( 1 - {e}^{\frac{- x}{λ}} ) \\ {I}_{B}^{n 0} = {I}_{oB} - {I}_{1 B} = {I}_{o} ( 1 - {e}^{\frac{- y}{λ}} ) \qquad ( 14 )$$

And the currents of neutral molecules (Iⁿ¹_{A}) and (Iⁿ¹_{B}) after the first recoiling back of the positive currents (I_{1A}) and (I_{1B}) from potential barriers as shown in FIG. 10:

$${I}_{A}^{n 1} = {I}_{1 B} - {I}_{2 B} = {I}_{1 B} ( 1 - {e}^{\frac{- ( x + y )}{λ}} ) = {I}_{o} {e}^{\frac{- y}{λ}} ( 1 - {e}^{\frac{- ( x + y )}{λ}} ) \\ {I}_{B}^{n 1} = {I}_{1 A} - {I}_{2 A} = {I}_{1 A} ( 1 - {e}^{\frac{- ( x + y )}{λ}} ) = {I}_{o} {e}^{\frac{- x}{λ}} ( 1 - {e}^{\frac{- ( x + y )}{λ}} ) \qquad ( 15 )$$

And the currents of neutral molecules (Iⁿ²_{A}) and (Iⁿ²_{B}) after the second recoiling back:

$${I}_{A}^{n 2} = {I}_{2 A} - {I}_{3 A} = {I}_{2 A} ( 1 - {e}^{\frac{- y}{λ}} ) = {I}_{o} {e}^{\frac{- ( 2 x + y )}{λ}} ( 1 - {e}^{\frac{- y}{λ}} ) \\ {I}_{B}^{n 2} = {I}_{2 B} - {I}_{3 B} = {I}_{2 B} ( 1 - {e}^{\frac{- x}{λ}} ) = {I}_{o} {e}^{\frac{- ( x + 2 y )}{λ}} ( 1 - {e}^{\frac{- x}{λ}} ) \qquad ( 16 )$$

The total currents of neutral molecules (Iⁿ_{A}) and (Iⁿ_{B}) can be derived from:

Iⁿ_{A}≅Iⁿ⁰_{A}+Iⁿ¹_{A}+Iⁿ²_{A}

Iⁿ_{B}≅Iⁿ⁰_{B}+Iⁿ¹_{B}+Iⁿ²_{B} (17)

The approximation used in equation (17) can be justified by that the distance transported by the two released positive currents (2x+2y) are large compared to the mean free path λ, then the two released positive currents will dissipate most of their energy through collisions after transporting this distance. Then from equations (14), (15), (16) and (17), the net current (Iⁿ) can be derived from:

$${I}^{n} = {I}_{B}^{n} - {I}_{A}^{n} \\ {I}_{A}^{n} = {I}_{o} ( 1 - {e}^{\frac{- x}{λ}} ) + {I}_{o} {e}^{\frac{- y}{λ}} ( 1 - {e}^{\frac{- y}{λ}} ) + {I}_{o} {e}^{\frac{- ( 2 x + y )}{λ}} ( 1 - {e}^{\frac{- y}{λ}} ) \\ {I}_{B}^{n} = {I}_{o} ( 1 - {e}^{\frac{- y}{λ}} ) + {I}_{o} {e}^{\frac{- x}{λ}} ( 1 - {e}^{\frac{- x}{λ}} ) + {I}_{o} {e}^{\frac{- ( x + 2 y )}{λ}} ( 1 - {e}^{\frac{- x}{λ}} ) \qquad ( 18 )$$

So that:

$${I}^{n} = 2 {I}_{o} ( {e}^{\frac{- x}{λ}} - {e}^{\frac{- y}{λ}} ) + {I}_{o} ( {e}^{\frac{- 2 y}{λ}} - {e}^{\frac{- 2 x}{λ}} ) + {I}_{o} ( {e}^{\frac{- ( x + 2 y )}{λ}} - {e}^{\frac{- ( 2 x + y )}{λ}} ) \qquad ( 19 )$$

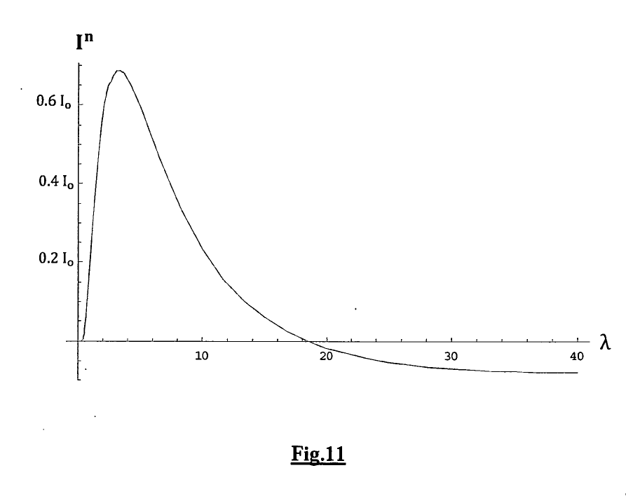

The relation between the net current of neutral molecules (Iⁿ) and the mean free path (λ) is shown in FIG. 11, with the assumptions:
x=2 distance units
y=10 distance units
   where in FIG. 11, the net current of neutral molecules (Iⁿ) has units of (Iₒ) and the mean free path (λ) has distance units. From FIG. 11, a local maximum value of (Iⁿ≅0.7 Iₒ) exist at some value of (λ˜4 distance units), assuming the distance units is (cm); this result implies that the mixed gas contained in the circular pipe should have low pressure.

### REFERENCES

1. Michigan State University. Electric Potential Field due to Point Charges Applet. W. Bauer, W. Benenson, G. Kortemeyer, and G. Westfall. https://www.msu.edu/˜brechtjo/physics/eField/eField.html
2. Modern Physics, Michael Fowler, University of Virginia. Kinetic Theory of Gases: A Brief Review. http://galileo.phys.virginia.edu/classes/252/kinetic_theory.html
3. Glenn F. Knoll, Radiation Detection and Measurement, 3rd edition, ISBN-10: 0471073385, p. 31, Wiley and Sons, 2000.
4. HyperPhysics, interactive physics course. Georgia State University.

1- A Thermoelectric Power Generator comprising: an electrical insulating circular closed pipe containing ionized gas mixed with stable gas under electric potential produced by a number of positive and negative electrodes distributed along the closed circular pipe, this distribution of positive and negative electrodes is a sequence of electrodes that carries an opposite charges located in a positions around the circular pipe. These electrode locations around the circular pipe have arc distances along the circular pipe equal to (d) between any two adjacent opposite charge type electrodes, and arc distance along the circular pipe equal to (D+d) between any two adjacent similar charge type electrodes, where the distance (D) is greater than the distance (d).

2- The thermoelectric power generator of claim 1, wherein the ionized gas molecules will be concentrated by electric field gradient produced by the electric potential of the positive and negative electrodes, this concentration volume of ionized gas molecules has a three dimensional oval shape produced because of that the distance (D) is greater than the distance (d) mentioned in claim 1.

3- The thermoelectric power generator of claim 1, the electrical recoiling of moving ionized gas molecules toward the ionized gas concentration volume is not similar from the different sides of the concentration volume mentioned in claim 2.

4- The usage of any number of the electrodes with the distance arrangement mentioned in claim 1 in interfering Brownian motion of the gas molecules.
